(19) United States
(12) Patent Application Publication
(10) Pub. No.: US 2016/0277035 A1
(43) Pub. Date: Sep. 22, 2016

(54) Non-Binary Low Density Parity Check Decoder With Format Transforming Variable Node Processor

(71) Applicant: Avago Technologies General IP (Singapore) Pte. Ltd., SG (SG)

(72) Inventors: Dan Liu, Shanghai (CN); Qi Zuo, Shanghai (CN); Lei Wang, Shanghai (CN); Shaohua Yang, San Jose, CA (US)

(21) Appl. No.: 14/661,059

(22) Filed: Mar. 18, 2015

(51) Int. Cl. H03M 13/11

(52) U.S. Cl. CPC H03M 13/114; H03M 13/1108

(57) ABSTRACT

A non-binary low density parity check decoder includes a check node processor configured to generate check node to variable node messages based on variable node to check node messages, and a variable node processor configured to generate the variable node to check node messages and to calculate perceived values of variable nodes based on the check node to variable node messages. The variable node to check node messages and the check node to variable node messages are in a normalized format. The variable node processor includes an adder configured to add likelihood values in a non-normalized format, wherein only one of two inputs to the adder are converted from the normalized format to the non-normalized format in a zero-padding circuit.

### FIELD OF THE INVENTION

Various embodiments of the present invention provide systems and methods for low density parity check decoding.

### BACKGROUND

Various data processing systems have been developed including storage systems, cellular telephone systems, and radio transmission systems. In such systems data is transferred from a sender to a receiver via some medium. For example, in a storage system, data is sent from a sender (i.e., a write function) to a receiver (i.e., a read function) via a storage medium. As information is stored and transmitted in the form of digital data, errors are introduced that, if not corrected, can corrupt the data and render the information unusable. The effectiveness of any transfer is impacted by any losses in data caused by various factors. Many types of error checking systems have been developed to detect and correct errors in digital data. For example, parity bits can be added to groups of data bits, ensuring that the groups of data bits (including the parity bits) have either even or odd numbers of ones, and used in error correction systems such as Low Density Parity Check (LDPC) decoders.

### BRIEF SUMMARY

Some embodiments of the present invention provide a non-binary low density parity check decoder including a check node processor configured to generate check node to variable node messages based on variable node to check node messages, and a variable node processor configured to generate the variable node to check node messages and to calculate perceived values of variable nodes based on the check node to variable node messages. The variable node to check node messages and the check node to variable node messages are in a normalized format. The variable node processor includes an adder configured to add likelihood values in a non-normalized format, wherein only one of two inputs to the adder are converted from the normalized format to the non-normalized format in a zero-padding circuit.

This summary provides only a general outline of some embodiments according to the present invention. Many other embodiments of the present invention will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals are used throughout several figures to refer to similar components.

FIG. 1 depicts a Tanner graph of a low density parity check code that can be decoded in a non-binary low density parity check decoder with a format transforming variable node processor in accordance with one or more embodiments of the present invention;

FIG. 2 depicts a non-binary layered low density parity check decoder with a format transforming variable node processor in accordance with one or more embodiments of the present invention;

FIG. 3 depicts a portion of a format transforming variable node processor including a zero-padding circuit, adder/subtraction circuit and normalizing circuit in accordance with one or more embodiments of the present invention;

FIGS. 4A-4B depict a combined normalizing and rearranging circuit suitable for use in a format transforming variable node processor in accordance with one or more embodiments of the present invention;

FIG. 5 depicts a flow diagram of an operation for performing variable node updates including format transformations in a low density parity check decoder in accordance with one or more embodiments of the present invention;

FIG. 6 depicts a block diagram of a non-binary low density parity check decoder with a format transforming variable node processor in accordance with one or more embodiments of the present invention;

FIG. 7 depicts a storage system including a non-binary low density parity check decoder with a format transforming variable node processor in accordance with one or more embodiments of the present invention;

FIG. 8 depicts a wireless communication system including a non-binary low density parity check decoder with a format transforming variable node processor in accordance with one or more embodiments of the present invention; and

FIG. 9 depicts another storage system including a data processing circuit having a non-binary low density parity check decoder with a format transforming variable node processor in accordance with one or more embodiments of the present invention.

### DETAILED DESCRIPTION OF THE INVENTION

Embodiments of the present invention are related to a non-binary low density parity check decoder with a format transforming variable node processor, either layered or non-layered, and using any check node processing algorithm, such as, but not limited to, a min-sum based check node processing algorithm. Low density parity check technology is applicable to transmission of information over virtually any channel or storage of information on virtually any media. Transmission applications include, but are not limited to, optical fiber, radio frequency channels, wired or wireless local area networks, digital subscriber line technologies, wireless cellular, Ethernet over any medium such as copper or optical fiber, cable channels such as cable television, and Earth-satellite communications. Storage applications include, but are not limited to, hard disk drives, compact disks, digital video disks, magnetic tapes and memory devices such as DRAM, NAND flash, NOR flash, other non-volatile memories and solid state drives.

A low density parity check code is defined by a sparse parity check matrix H of size m×n, where m<n. A codeword c of length n satisfies all the m parity check equations defined by H, i.e., cH^{T}=0, where 0 is a zero vector. Decoder convergence is checked by determining whether the syndrome s=cH^{T} is all zero. The syndrome is a vector of length m, with each bit corresponding to a parity check. A zero bit in a syndrome means the check is satisfied, while a non-zero bit in the syndrome is an unsatisfied check (USC). By definition, a codeword has syndrome s=0. A non-codeword has a non-zero syndrome.

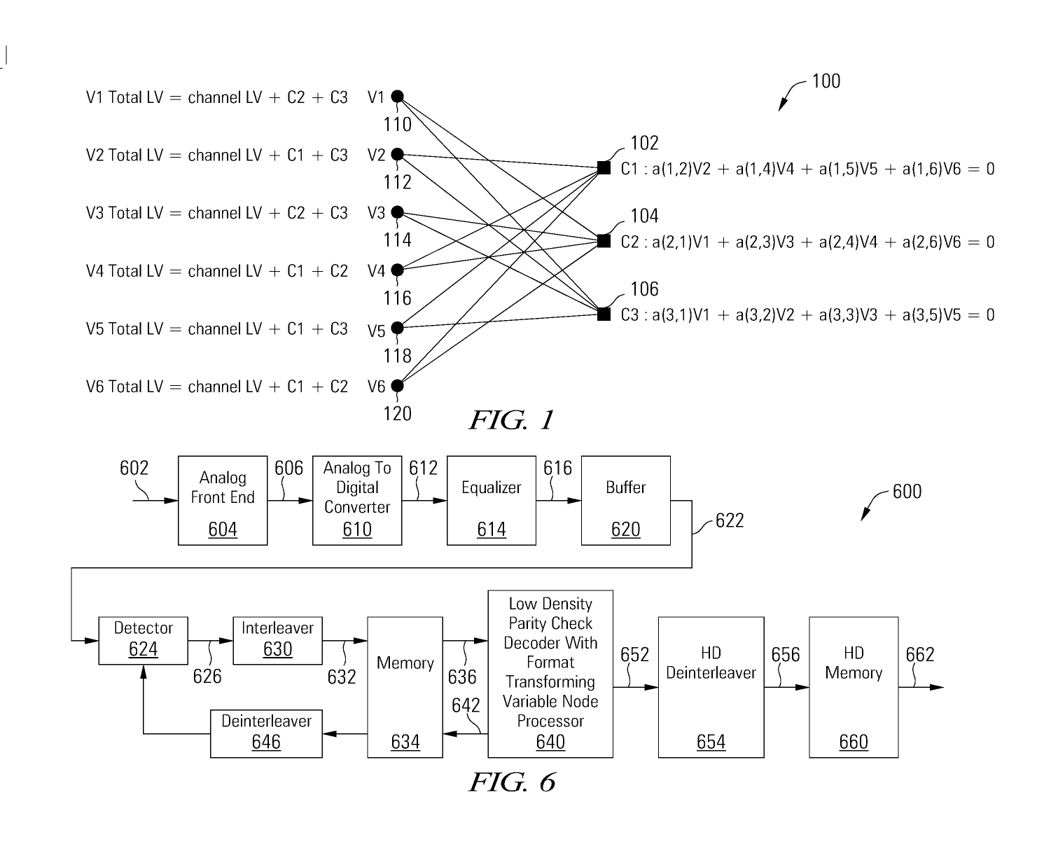

Low density parity check codes are also known as graph-based codes with iterative decoding algorithms, which can be visually represented in a Tanner graph 100 as illustrated in FIG. 1. In a low density parity check decoder, multiple parity checks are performed in a number of check nodes 102, 104 and 106 for a group of variable nodes 110, 112, 114, 116, 118, and 120. The connections (or edges) between variable nodes 110-120 and check nodes 102-106 are selected as the low density parity check code is designed, balancing the strength of the code against the complexity of the decoder required to execute the low density parity check code as data is obtained. The number and placement of parity bits in the group are selected as the low density parity check code is designed. Messages are passed between connected variable nodes 110-120 and check nodes 102-106 in an iterative process, passing beliefs about the values that should appear in variable nodes 110-120 to connected check nodes 102-106. Parity checks are performed in the check nodes 102-106 based on the messages and the results are returned to connected variable nodes 110-120 to update the beliefs if necessary.

In a non-binary low density parity check decoder, variable nodes 110-120 contain symbols from a Galois Field, a finite field GF(p^{k}) that contains a finite number of elements, characterized by size p^{k} where p is a prime number and k is a positive integer. Messages representing variable node values in the non-binary low density parity check decoders are multi-dimensional vectors, containing likelihood values representing the probability that the sending variable node contains a particular value. The term “likelihood value” is used herein to refer to a likelihood or probability that a symbol has a particular value, whether it is represented as a plain-likelihood probability value, a log likelihood ratio (LLR) value, or any other representation of a likelihood.

The connections between variable nodes 110-120 and check nodes 102-106 can be presented in matrix form, where columns represent variable nodes, rows represent check nodes, and a random non-zero element a(i,j) from the Galois Field at the intersection of a variable node column and a check node row indicates a connection between that variable node and check node and provides a permutation for messages between that variable node and check node:

$$H = [ \begin{matrix}0 & a ( 1 , 2 ) & 0 & a ( 1 , 4 ) & a ( 1 , 5 ) & a ( 1 , 6 ) \\ a ( 2 , 1 ) & 0 & a ( 2 , 3 ) & a ( 2 , 4 ) & 0 & a ( 2 , 6 ) \\ a ( 3 , 1 ) & a ( 3 , 2 ) & a ( 3 , 3 ) & 0 & a ( 3 , 5 ) & 0\end{matrix} ]$$

For example, in some embodiments of a GF(4) decoder, each Galois Field element a(i,j) specifies a shift for the corresponding circulant matrix of 0, 1, 2 or 3.

The non-binary layered low density parity check decoder uses quasi-cyclic codes in which the parity check H matrix is a matrix of circulant sub-matrices, which are cyclically shifted versions of identity matrices and null matrices with different cyclical shifts specified by the H matrix non-zero entry values a(i,j). Each circulant P_{i,j} is a p×p sub-matrix with the form:

$${P}_{i , j} = [ \begin{matrix}0 & α & 0 & … & 0 \\ 0 & 0 & α & … & 0 \\ ⋮ & ⋮ & ⋮ & ⋱ & ⋮ \\ 0 & 0 & 0 & … & α \\ α & 0 & 0 & … & 0\end{matrix} ]$$

where entry value α is an element over the Galois Field GF(2^{m}), which has 2^{m-1} possible values. When m>1, the low density parity check code is non-binary. In the special case when m=1, the low density parity check code is binary.

In some embodiments, the entry value α is randomly selected from the Galois Field. The entry value α provides a permutation for messages between the variable node and check node connected by the entry, where a multiplication in the Galois Field of the message by the current layer entry value is performed. This permutation, performed by the variable node unit or variable node processor in the non-binary layered low density parity check decoder with normalized input and output, is also referred to herein as rearranging. Similarly, when messages are passed back from a check node to a variable node, the messages are inverse-rearranged by the previous layer entry value, where a division in the Galois Field of the message by the current layer entry value is performed.

By providing multiple check nodes 102-106 for the group of variable nodes 110-120, redundancy in error checking is provided, enabling errors to be corrected as well as detected.

Each check node 102-106 performs a parity check on bits or symbols passed as messages from its neighboring (or connected) variable nodes. In the example low density parity check code corresponding to the Tanner graph 100 of FIG. 1, check node 102 checks the parity of variable nodes 112, 116, 118 and 120. Perceived values of a variable node are updated based on the parity check results from connected check nodes. For example, the perceived value or likelihood value (LV) of variable node 110 is updated based on the channel likelihood value or previous likelihood value, along with the check node messages (C2, C3) from connected check nodes 104, 106. Values are passed back and forth between connected variable nodes 110-120 and check nodes 102-106 in an iterative process until the low density parity check code converges on a value for the group of data and parity bits in the variable nodes 110-120, or until a maximum number of iterations is reached. For example, variable node 110 passes messages to check nodes 104 and 106, referred to herein as variable node to check node messages or V2C messages. Check node 102 passes messages back to variable nodes 112, 116, 118 and 120, referred to herein as check node to variable node messages or C2V messages. The messages between variable nodes 110-120 and check nodes 102-106 are probabilities or beliefs, thus the low density parity check decoding algorithm is also referred to as a belief propagation algorithm. Each message from a node represents the probability that a bit or symbol has a certain value based on the current value of the node and on previous messages to the node.

A message from a variable node to any particular neighboring check node is computed using any of a number of algorithms based on the current value of the variable node and the last messages to the variable node from neighboring check nodes, except that the last message from that particular check node is omitted from the calculation to prevent positive feedback. Similarly, a message from a check node to any particular neighboring variable node is computed based on the current value of the check node and the last messages to the check node from neighboring variable nodes, except that the last message from that particular variable node is omitted from the calculation to prevent positive feedback. As local decoding iterations are performed in the system, messages pass back and forth between variable nodes 110-120 and check nodes 102-106, with the values in the nodes 102-120 being adjusted based on the messages that are passed, until the values converge and stop changing or until a maximum number of iterations is reached.

In a non-binary layered low density parity check decoder, the parity check H matrix is partitioned into L layers, with the H matrix being processed row by row and the circulants being processed layer by layer. As the rows are processed, the column results are updated based on each row result. Layered decoding can reduce the time to converge on a result in the decoder in some cases. The optimized variable node processor that performs format transformation disclosed herein can be used in both layered and non-layered low density parity check decoders.

Likelihood values in the low density parity check decoder are represented in multiple different formats, an absolute format and a normalized format that reduces memory requirements. In the absolute or non-normalized format, a likelihood value for a symbol or variable node contains the probability for each element of the Galois Field that the symbol or variable node has the value of that element. Thus, for a GF(q) decoder, a likelihood value for a symbol will contain q probabilities, giving the likelihoods that the symbol has the value of each of the q Galois Field elements. In the normalized format, the likelihood value contains a hard decision identifying the Galois Field element with the most likely value of the symbol, and probabilities for the values of the remaining Galois Field elements, each normalized to the likelihood of the most likely Galois Field element. Thus, for a GF(q) decoder, a normalized likelihood value for a symbol will contain a hard decision and q-1 probabilities, giving the most likely symbol value and the likelihoods that the symbol has the value of each of the remaining q-1 Galois Field elements, normalized to the likelihood of the most likely element. As an example, in a GF(4) decoder, each symbol has 4 possible values. The non-zero value in the H matrix will take 3 possible values (1,2,3). Therefore the soft information in the GF(4) iterative decoding system will contain 4 LLRs, LLR(i) (i=0,1,2,3) which represent the probability in the log domain that the symbol has value “i”. The normalized LLR format of the GF(4) symbols is defined as (HD, 11r0, 11r1, 11r2), where HD represents the hard decision, the most likely value among all 4 possible values. LLRi (i=0,1,2) is the soft information relative to the most likely value. The following table sets forth the hard decisions and normalized LLRs for the four possible symbol values from the Galois Field:

TABLE 1

| | HD | LLR0 | LLR1 | LLR2 |
|---|---|---|---|---|
| LLR related | 00 | 01 | 10 | 11 |
| to symbols | 01 | 00 | 11 | 10 |
| | 10 | 11 | 00 | 01 |
| | 11 | 10 | 01 | 00 |

where the three log likelihood ratio values LLR0, LLR1, LLR2 are calculated as follows:

if hd=00, LLR0=log(Probability(hd=01))−log(Probability(hd=00));

if hd=00, LLR1=log(Probability(hd=10))−log(Probability(hd=00));

if hd=00, LLR2=log(Probability(hd=11))−log(Probability(hd=00));

if hd=01, LLR0=log(Probability(hd=00))−log(Probability(hd=01));

if hd=01, LLR1=log(Probability(hd=11))−log(Probability(hd=01));

if hd=01, LLR2=log(Probability(hd=10))−log(Probability(hd=01));

if hd=10, LLR0=log(Probability(hd=11))−log(Probability(hd=10));

if hd=10, LLR1=log(Probability(hd=00))−log(Probability(hd=10));

if hd=10, LLR2=log(Probability(hd=01))−log(Probability(hd=10));

if hd=11, LLR0=log(Probability(hd=10))−log(Probability(hd=11));

if hd=11, LLR1=log(Probability(hd=01))−log(Probability(hd=11));

if hd=11, LLR2=log(Probability(hd=00))−log(Probability(hd=11));

To convert between the absolute and normalized formats, the variable node processor performs 0-padding and normalization operations as will be described in more detail below.

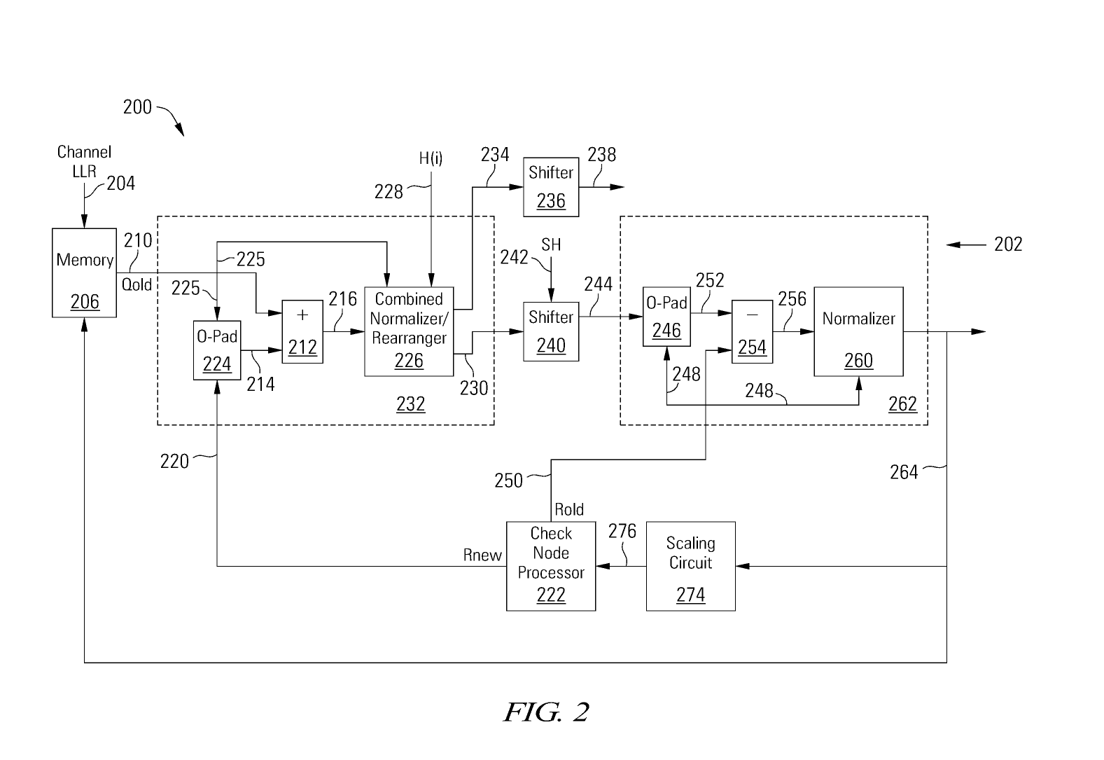

Turning to FIG. 2, a non-binary layered low density parity check decoder 200 with a format transforming variable node processor 202 is illustrated in block-diagram form in accordance with one or more embodiments of the present invention. Incoming likelihood values for data to be decoded are received at input 204 and stored in a decoder input buffer or memory 206 as initial Q values, or variable node likelihood values. The initial Q values received at input 204 are in normalized format, including a hard decision identifying the most likely element of the Galois Field as the value of a symbol, and soft data or LLR values representing the likelihood of ach of the remaining elements of the Galois Field as the values of the symbol.

The memory 206 yields stored Qold values 210 in normalized format for the layer previous to the layer currently being processed, also referred to herein as the previous layer and the connected layer. The stored Qold values 210 are therefore either initialized by channel likelihood values or calculated in a previous or earlier decoding iteration, and are therefore old Q values.

An adder 212 adds the Qold values 210 to previous layer check node to variable node messages or Rnew values 214, yielding a sum or S values 216 containing total likelihood values in absolute format for the previous layer. Again, columns in the H matrix represent variable nodes, and by adding all the non-zero entries in a column, the connected variable nodes are added to yield the input to a check node. The adder 214 can comprise any suitable circuitry for adding likelihood values, operating in array fashion in some embodiments. Based upon the disclosure provided herein, one of ordinary skill in the art will recognize a variety of circuits that may be included in adder 214.

Notably, while the Rnew values 214 are zero-padded versions of Rnew values 220 in check node to variable node messages from a check node processor 222, zero-padded in a zero-padding circuit 224, no zero-padding is performed on the Qold values 210 from the memory 206 prior to adding in adder circuit 212. Rather, the adder circuit 212 and a combined normalizing/rearranging circuit 226 in the variable node processor 202 are adapted to compensate, thereby avoiding the need for an extra zero-padding circuit to process the Qold values 210. The zero-padding circuit 224 generates an absolute format output based on a normalized format input according to Table 2 below, where the input is the normalized format Rnew values 220, with the hard decision HD1 of the Rnew values 220 corrected by XORing the corresponding hard decision HD0 225 of the Qold values 210. This correction, providing HD1̂HD0 (HD1 XOR HD0) as the hard decision input to the zero-padding circuit 224 rather than just HD1, acts in combination with the combined normalizing/rearranging circuit 226 in the variable node processor 202 to avoid the need for an extra zero-padding circuit to process the Qold values 210. The zero-padding circuit 224 inputs HD1̂HD0, LLR0, LLR1, LLR2 and corresponding outputs LLR0′, LLR1′, LLR2′, LLR3′ for the example GF(4) decoder are summarized in Table 2:

TABLE 2

| | HD1\hat{ }HD0 = | HD1\hat{ }HD0 = | HD1\hat{ }HD0 = | HD1\hat{ }HD0 = |
|---|---|---|---|---|
| | 00 | 01 | 02 | 03 |
| LLR0′ | 0 | LLR0 | LLR1 | LLR2 |
| LLR1′ | LLR0 | 0 | LLR2 | LLR1 |
| LLR2′ | LLR1 | LLR2 | 0 | LLR0 |
| LLR3′ | LLR2 | LLR1 | LLR0 | 0 |

The S values 216 are provided to a normalizing/rearranging circuit 226, which converts the format of the S values 216 from the absolute format of q LLR values to the equivalent content but different format of one hard decision and q-1 soft LLR values (for a GF(q) embodiment). The normalizing/rearranging circuit 226 also applies a permutation specified by the entry 228 in the H matrix to rearrange the variable node updated values to prepare for the check node update and to apply the permutations specified by the non-zero elements of the H matrix. The normalizing/rearranging circuit 226 yields P values 230 in normalized format for the previous layer at the output of the first section 232 of the variable node processor 202. As will be described in more detail below, the hard decision from the normalizing/rearranging circuit 226 is modified by XORing it with the corresponding hard decision HD0 225 of the Qold values 210.

The normalizing/rearranging circuit 226 also yields LLR values 234 which are provided to a cyclic shifter 236. Cyclic shifter 236 rearranges the LLR values 234 to column order, performs a barrel shift which shifts the normalized LLR values 234 from the previous layer to the current layer, and yields output hard decisions 238 calculated based on the LLR sums as argminₐ Sₙ(a).

The P values 230 from the normalizing/rearranging circuit 226 are provided to a barrel shifter 240, a cyclic shifter which shifts the symbol values in the normalized LLR P values 230 by a shift value SH 242 to generate the next circulant sub-matrix, yielding shifted P values 244 which contain the total soft LLR values of the current layer.

The shifted P values 244 are provided to zero-padding circuit 246, which generates an absolute format output based on a normalized format input. The zero-padding circuit 246 generates an absolute format output based on a normalized format input according to Table 2 below, where the input is the normalized format shifted P values 244, with the hard decision HD1 of the normalized format shifted P values 244 corrected by XORing the corresponding hard decision HD0 248 of the Rold values 250 in check node to variable node messages from the check node processor 222. This correction, providing HD1̂HD0 as the hard decision input to the zero-padding circuit 246 rather than just HD1, acts in combination with a normalizing circuit 260 in the second section 262 of the variable node processor 202 to avoid the need for an extra zero-padding circuit to process the Rold values 250.

The Rold values 250 in the check node to variable node messages from the check node processor 222 are subtracted from the absolute format shifted P values 252 from the zero-padding circuit 246 in a subtraction circuit 254. The subtraction circuit 254 thus subtracts the current layer check node to variable node messages, or Rold values 250, from the current layer P values 252, yielding current layer D messages 256. The current layer check node to variable node messages or Rold values 250 are old values for the current layer, generated during a previous decoding iteration. Generally, the vector message from a check node to a variable node contains the probabilities for each symbol din the Galois Field that the destination variable node contains that symbol d, based on the prior round variable node to check node messages from neighboring variable nodes other than the destination variable node. The inputs from neighboring variable nodes used in a check node to generate the check node to variable node message for a particular neighboring variable node are referred to as extrinsic inputs and include the prior round variable node to check node messages from all neighboring variable nodes except the particular neighboring variable node for which the check node to variable node message is being prepared, in order to avoid positive feedback. The check node prepares a different check node to variable node message for each connected variable node, using the different set of extrinsic inputs for each message based on the destination variable node. Subtracting the current layer check node to variable node messages or Rold values 250 from an earlier iteration removes the intrinsic input, leaving only the extrinsic inputs to generate a check node to variable node message for a variable node. The subtraction circuit 254 can comprise any suitable circuitry for subtracting likelihood values. Based upon the disclosure provided herein, one of ordinary skill in the art will recognize a variety of circuits that can be included in subtraction circuit 254.

D messages 256 are provided to the normalizing circuit 260 which converts the format of the D messages 256 from absolute format to normalized format, yielding Qnew messages 264 in normalized format. The Qnew messages 264 are output from the second part 202 of the variable node processor 202 and stored in memory 206 for subsequent decoding iterations, overwriting previous channel or calculated values for the current layer.

The Qnew messages 264 are also provided to a scaling circuit 274 as variable node to check node messages. The scaling circuit 274 reduces the precision of the Qnew messages 264, yielding scaled Qnew messages 276. The scaled Qnew messages 276 are provided to a check node processor 222, which applies parity checks to calculate check node to variable node messages including Rnew values 220 for the previous layer and Rold values 250 for the current layer. The check node processor 222 can calculate check node to variable node messages using any suitable check node algorithm, such as, but not limited to, a min-sum based algorithm. Based upon the disclosure provided herein, one of ordinary skill in the art will recognize a variety of check node processor circuits that can be used in relation to different embodiments of the present invention.

The variable node processor 202 and the check node processor 222 thus operate together to perform layered decoding of non-binary data. The variable node processor 202 generates variable node to check node messages 264 and calculates perceived values based on check node to variable node messages in old R messages 250 and new R messages 220. The term “perceived value” is used herein to refer to the value of symbols to be decoded, and in some embodiments, is represented by likelihood values. The check node processor 222 generates check node to variable node messages 220, 250. During operation of the low density parity check layer decoder 200, as Q values and R values are iteratively circulated through the decoder 200, parity checks are calculated based on decoder output 238. If the number of unsatisfied parity checks is equal to zero after all layers have been processed, the low density parity check layer decoder 200 has converged and processing can be halted.

In summary, the variable node processor 202 performs format transformation of signals between absolute format with an LLR value for each element of the Galois Field and a normalized format with a hard decision identifying the most likely element of the Galois Field for the symbol and LLR values for the remaining elements of the Galois Field. By using a normalized format for some operations in the variable node processor 202, memory requirements are reduced because the hard decision is an index value and requires less memory to store than the LLR value for the most likely Galois Field element.

The first section 232 of the variable node processor 202 receives the Qold values 210 in normalized format for the previous layer, and is able to add the Qold values 210 in adder 212 without the use of a zero-padding circuit to transform from normalized to absolute format. The hard decision in the Rnew values 220 is corrected using the hard decision of the Qold values 210 (Qold_hd̂Rnew_hd), and is then transformed from normalized format to absolute format in zero-padding circuit 224. The Qold values 210 are added to the Rnew values 220 in adder 212, yielding a sum 216 in absolute format. The combined normalizing/rearranging circuit 226 then combines the normalizing and rearranging functions on the sum 216, reducing the data switching multiplexers required. Finally, the hard decisions in the normalizing/rearranging circuit 226 are corrected using the hard decision of the Qold values 210 (Qold_hd̂hd) to yield the final P values 230 as the output of the first section 232 of the variable node processor 202.

Similarly, the second section 262 of the variable node processor 202 receives the shifted P values 244, delta shifted in shifter 240, and is able to subtract the Rold values 250 from the shifted P values 244 without the use of a zero-padding circuit to transform the Rold values 250 from normalized to absolute format. The hard decisions in the shifted P values 244 are corrected using the hard decisions of the Rold values 250 (P_hd̂Rold_hd), and are then transformed from normalized format to absolute format in zero-padding circuit 246. The Rold values 250 are subtracted from the shifted P values 244 in subtraction circuit 254, yielding difference 256 in absolute format. The normalizing circuit 260 converts the difference to normalized format, and the hard decisions in the normalizing circuit 260 are corrected using the hard decisions of the Rold values 250 (D_hd̂Rold_hd) to yield the Qnew values 264 as the output of the second section 262 of the variable node processor 202.

Again, the variable node processor with format transformation disclosed herein can be applied to both layered and non-layered low density parity check decoders. Similarly, the low density parity check decoder can be adapted to any number of parallel data paths, processing multiple symbols and/or circulants in parallel. The optimized format transformation performed in the variable node processor avoids the need for zero-padding circuits to process the Qold values 210 and Rold values 250, and reduces the multiplexers needed for normalizing and rearranging in the combined normalizer/rearranger circuit 226. These circuit savings are multiplied as the number of symbols processed in parallel in the low density parity check decoder is increased.

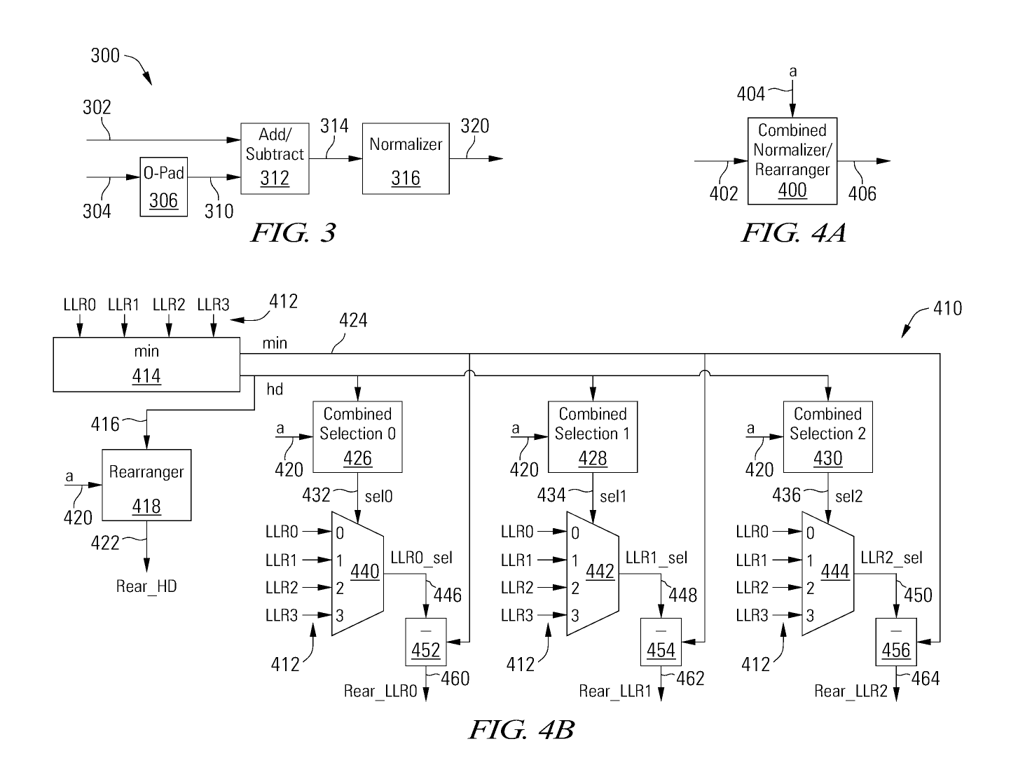

Turning now to FIG. 3, a portion 300 of a format transforming variable node processor is depicted including a zero-padding circuit 306, adder/subtraction circuit 312 and normalizing circuit 316 in accordance with one or more embodiments of the present invention. If used in the first section (e.g., 232) of a variable node processor 202, the adder/subtraction circuit 312 comprises an adder and the normalizing circuit 316 performs both normalizing and rearranging.

If used in the second section (e.g., 262) of a variable node processor 202, the adder/subtraction circuit 312 comprises a subtraction circuit and the normalizing circuit 316 does not perform rearranging.

The input 302 to the adder/subtraction circuit 312 carries the first operand, Sᵢₙ0, which is in normalized format and which includes a hard decision hd0 and three LLR values LLR0, LLR1 and LLR2 in a GF(4) decoder. Because the adder/subtraction circuit 312 expects four LLR values in the first operand for a GF(4) decoder, the first operand at the input to the adder/subtraction circuit 312 uses the value 0 for the first LLR value corresponding to the hard decision. Thus, whereas input 302 carries (hd0, LLR0, LLR1, LLR2) for a symbol, the first operand Sᵢₙ0′ at the input to the adder/subtraction circuit 312 is (0, LLR0, LLR1, LLR2).

The input 304 to the zero-padding circuit 306 is in normalized format and includes a hard decision hd0 and three LLR values LLR0, LLR1 and LLR2 in a GF(4) decoder, with the hard decision hd0 corrected by XORing it with the hard decision hd0 from the first operand Sᵢₙ0 at input 302. Thus, the input 304 to the zero-padding circuit 306 is (hd1̂hd0, LLR0, LLR1, LLR2). If used in the first section (e.g., 232) of a layered variable node processor 202, the input 304 to the zero-padding circuit 306 is based on an Rnew value (e.g., 220) in normalized format, or (hd0, LLR0, LLR1, LLR2). The zero-padding circuit 306 generates an output 310 based on the input 304 according to Table 2 above. The output 310 is used as the second operand Sᵢₙ1′ (LLR0′LLR1′, LLR2′, LLR3′) at the second input to the adder/subtraction circuit 312.

The adder/subtraction circuit 312 performs either an addition operation when used in the first section (e.g., 232 ) of a layered variable node processor 202 or a subtraction operation when used in the second section (e.g., 262) of a layered variable node processor 202, yielding output Sum' 314 in absolute format (LLR0, LLR1, LLR2, LLR3). The adder/subtraction circuit 312 includes four adders or subtractors for a GF(4) decoder, for example adding LLR0′ from Sᵢₙ0′ to LLR0′ from Sᵢₙ1′ to yield LLR0, adding LLR1′ from Sᵢₙ0′ to LLR1′ from Sᵢₙ1′to yield LLR1, etc.

The normalizing circuit 316 normalizes the absolute format Sum’ 314 in absolute format (LLR0, LLR1, LLR2, LLR3) to yield output 320 Sum (hd̂hd0, LLR0, LLR1, LLR2) in normalized format. Notably, the hard decision at the output of the normalizing circuit 316 is corrected by XORing it with the hard decision hd0 from the first operand Sᵢₙ0 at input 302, thus (hd̂hd0). Where used in the first section (e.g., 232) of a layered variable node processor 202, the normalizing circuit 316 also rearranges the output as it is normalized in a combined normalizing/rearranging process with reduced data multiplexing requirements. However, the normalization performed in normalizing circuit 316 can be represented in Table 3:

TABLE 3

| | min = llr0′ | min = llr1′ | min = llr2′ | min = llr3′ |
|---|---|---|---|---|
| hd\hat{ }hd0 | 00 | 01 | 10 | 11 |
| LLR0 | LLR1′-min | LLR0′-min | LLR3′-min | LLR2′-min |
| LLR1 | LLR2′-min | LLR3′-min | LLR0′-min | LLR1′-min |
| LLR2 | LLR3′-min | LLR2′-min | LLR1′-min | LLR0′-min |

Again, the rearranging or permutation of LLR values in the first section (e.g., 232) of a layered variable node processor 202 is performed in combination with the normalizing. However, to illustrate the result of the rearranging, the result of the rearranging function is summarized in Table 4:

TABLE 4

| | Rear_LLR0 | Rear_LLR1 | Rear_LLR2 |
|---|---|---|---|
| a = 1 | LLR0′ | LLR1′ | LLR2′ |
| a = 2 | LLR2′ | LLR0′ | LLR1′ |
| a = 3 | LLR1′ | LLR2′ | LLR0′ |

where a or alpha is the rearranging or permutation factor read from the non-zero entries of the circulant sub-matrix and is an element of the Galois Field, where LLR0′, LLR1′ and LLR2′ are the input LLR values, and where Rear_LLR0, Rear LLR1 and Rear LLR2 are the output LLR values, rearranged by the permutation factor. Again, the permutation factor specifies a multiplication in the Galois Field of the indexes of the LLR values by the current layer circulant sub-matrix entry. This multiplication rearranges the indexes of the LLR values. For example, in a GF(4) embodiment in which the four elements 0-3 of the Galois Field are indexed by 0, 1, α, α², the multiplication in the Galois Field rearranged the entries in the Galois Field. Element 2 (α) multiplied by element 1 (1) equals α×1 or α, which is element 2. Similarly, element 2×2=α×α=α², which is element 3. Element 2×3=α×α²=1, which is element 1. Thus, element 2 multiplied by either 1, 2 and 3 results in elements 2, 3, and 1, respectively, which are permutations of elements 1, 2 and 3.

Turning to FIG. 4A, a combined normalizing and rearranging circuit 400 receives an input 402 in absolute format as (LLR0, LLR1, LLR2, LLR3). The combined normalizing and rearranging circuit 400 both normalizes and rearranges the likelihood values according to a permutation or rearranging factor a 404, yielding normalized and rearranged output 406 in normalized format as (Rear_hd, Rear_LLR0, Rear_LLR1, Rear_LLR2).

Turning to FIG. 4B, details of one embodiment of a combined normalizing and rearranging circuit 410 are depicted. A minimum detection circuit 414 receives an absolute format input 412. In a GF(4) decoder, four LLR values LLR0, LLR1, LLR2, LLR3 are received at input 412. The minimum detection circuit 414 compares the LLR values at input 412 and identifies the lowest LLR value, outputting the index of the lowest LLR value as the hard decision 416 and the actual lowest LLR value as the min 424. A hard decision rearranging circuit 418 permutes the hard decision 416 by the permutation factor 420, yielding a rearranged hard decision 422. Again, the hard decision 416 is an index to an entry in the Galois Field, which is multiplied in the rearranging circuit 418 by the permutation factor 420 to yield the rearranged hard decision 422, a permuted index to another entry in the Galois Field.

The hard decision 416 is also provided to combined selection circuits 426, 428, 430, which calculate selection values 432, 434, 436 based on the permutation factor 420. The combined selection circuits 426, 428, 430 associate either LLR0, LLR1, LLR2 or LLR3 with each of a selected LLR0, LLR1 or LLR2 to achieve the rearranging specified by the permutation factor 420. As an example, the combined select logic applied by combined selection circuit 426 is specified using the following ternary or conditional if-then-else operators:
Sel0=(a=1) ? {hd[1],˜hd[0]}: (a=2) ? {˜hd[1], ˜hd[0]}: {˜hd[1], hd[0]};
Sel1=(a=1) ? {˜hd[1],hd[0]}: (a=2) ? {hd[1],˜hd[0]}: {˜hd[1],˜hd[0]};
Sel2=(a=1) ? {˜hd[1],˜hd[0]}: (a=2) ? {˜hd[1],hd[0]}: {hd[1],˜hd[0]};

Multiplexers 440, 442, 444 assign either LLR0, LLR1, LLR2 or LLR3 to each of three outputs LLR0_sel 446, LLR1_sel 448 and LLR2_sel 450, based upon the outputs 432, 434, 436 of the combined selection circuits 426, 428, 430. Subtraction circuits 452, 454, 456 subtract the minimum input LLR 424 from each of LLR0_sel 446, LLR1_sel 448 and LLR2_sel 450, yielding rearranged LLR values Rear_LLR0 460, Rear_LLR1 462, Rear_LLR2 464. Thus, the combined normalizing and rearranging circuit 410 both normalizes and rearranges the input 412, combining the normalizing and rearranging to avoid using separate multiplexers in each of the two operations.

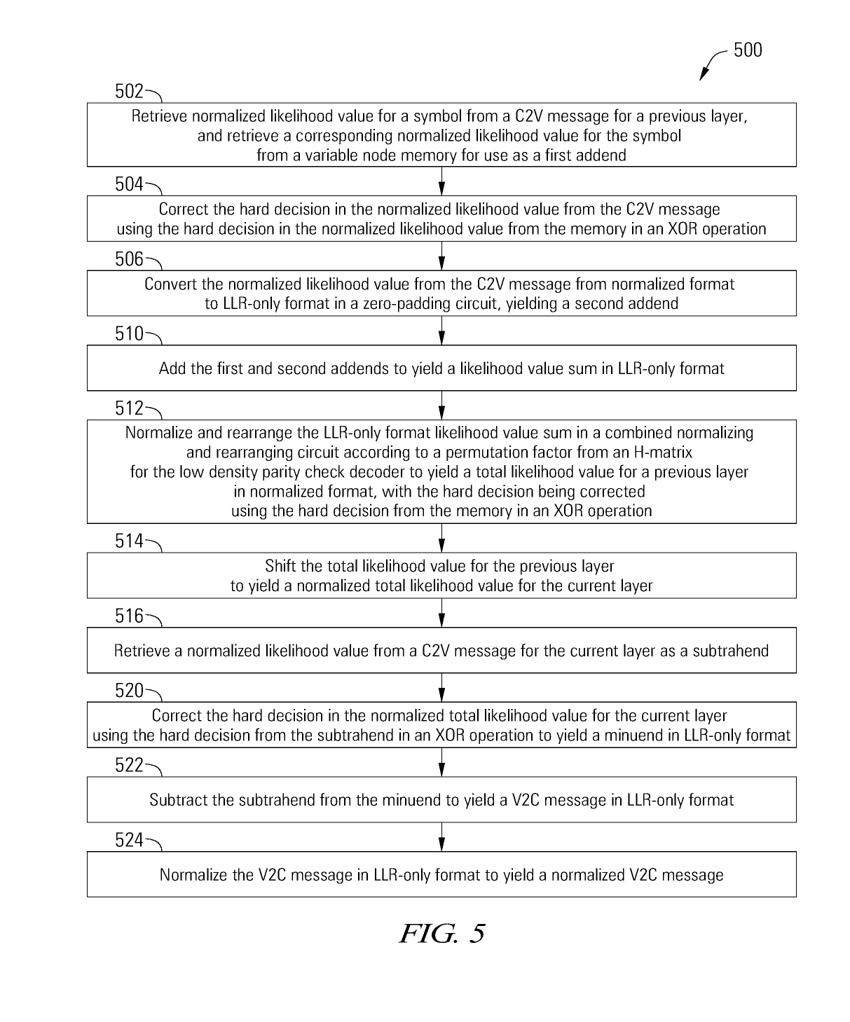

Turning to FIG. 5, a flow diagram 500 depicts a method for performing variable node updates in a layered low density parity check decoder in accordance with one or more embodiments of the present invention. Following flow diagram 500, a normalized likelihood value for a symbol is retrieved from a check node to variable node (C2V) message for a previous layer, and a corresponding normalized likelihood value for the symbol is retrieved from a variable node memory for use as a first addend. (Block 502) The hard decision in the normalized likelihood value from the check node to variable node message is corrected using the hard decision from the memory in an XOR operation. (Block 504) The normalized likelihood value from the check node to variable node message is converted from normalized format to LLR-only format in a zero-padding circuit, yielding a second addend. (Block 506) The first and second addends are added to yield a likelihood value sum in LLR-only format. (Block 510) The likelihood value sum in LLR-only format is normalized and rearranged in a combined normalizing and rearranging circuit according to a permutation factor from an H-matrix for the low density parity check decoder to yield a total likelihood value for a previous layer in normalized format, with the hard decision being corrected using the hard decision from the memory in an XOR operation. (Block 512 ) The total likelihood value for the previous layer is shifted to yield a normalized total likelihood value for the current layer. (Block 514 ) A normalized likelihood value is retrieved from a check node to variable node message for the current layer as a subtrahend. (Block 516) The hard decision in the normalized total likelihood value for the current layer is corrected using the hard decision from the subtrahend in an XOR operation to yield a minuend in LLR-only format. (Block 520) The subtrahend is subtracted from the minuend to yield a variable node to check node (V2C) message in LLR-only format. (Block 522) The variable node to check node message in LLR-only format is normalized to yield a normalized variable node to check node message. (Block 524)

Although the non-binary low density parity check decoder with a format transforming variable node processor disclosed herein is not limited to any particular application, several examples of applications are presented herein that benefit from embodiments of the present invention. Turning to FIG. 6, a read channel 600 with non-binary low density parity check decoder with a format transforming variable node processor 640 is depicted in accordance with one or more embodiments of the present invention. The read channel 600 is used to process an analog signal 602 and to retrieve user data bits from the analog signal 602 without errors. In some cases, analog signal 602 is derived from a read/write head assembly in a magnetic storage medium. In other cases, analog signal 602 is derived from a receiver circuit that is operable to receive a signal from a transmission medium. The transmission medium may be wireless or wired such as, but not limited to, cable or optical connectivity. Based upon the disclosure provided herein, one of ordinary skill in the art will recognize a variety of sources from which analog signal 602 can be derived.

The read channel 600 includes an analog front end 604 that receives and processes the analog signal 602. Analog front end 604 may include, but is not limited to, an analog filter and an amplifier circuit as are known in the art. Based upon the disclosure provided herein, one of ordinary skill in the art will recognize a variety of circuitry that may be included as part of analog front end 604. In some cases, the gain of a variable gain amplifier included as part of analog front end 604 may be modifiable, and the cutoff frequency and boost of an analog filter included in analog front end 604 may be modifiable. Analog front end 604 receives and processes the analog signal 602, and provides a processed analog signal 606 to an analog to digital converter 610.

Analog to digital converter 610 converts processed analog signal 606 into a corresponding series of digital samples 612. Analog to digital converter 610 may be any circuit known in the art that is capable of producing digital samples corresponding to an analog input signal. Based upon the disclosure provided herein, one of ordinary skill in the art will recognize a variety of analog to digital converter circuits that may be used in relation to different embodiments of the present invention. In other embodiments, digital data is retrieved directly from a storage device or other source, such as a flash memory. Digital samples 612 are provided to an equalizer 614. Equalizer 614 applies an equalization algorithm to digital samples 612 to yield an equalized output 616. In some embodiments of the present invention, equalizer 614 is a digital finite impulse response filter circuit as is known in the art. Data or codewords contained in equalized output 616 may be stored in a buffer 620 until a data detector 624 is available for processing and ready to receive stored equalized samples 622.

The data detector 624 performs a data detection process on the received input, resulting in a detected output 626. In some embodiments of the present invention, data detector 624 is a Viterbi algorithm data detector circuit, or a maximum a posteriori (MAP) data detector circuit as is known in the art. In these embodiments, the detected output 626 contains log likelihood ratio information about the likelihood that each bit or symbol has a particular value. Based upon the disclosure provided herein, one of ordinary skill in the art will recognize a variety of data detectors that may be used in relation to different embodiments of the present invention. Data detector 624 is started based upon availability of a data set in buffer 620 from equalizer 614 or another source.

The detected output 626 from data detector 624 is provided to an interleaver 630 that protects data against burst errors. Burst errors overwrite localized groups or bunches of bits. Because low density parity check decoders are best suited to correcting errors that are more uniformly distributed, burst errors can overwhelm low density parity check decoders. The interleaver 630 prevents this by interleaving or shuffling the detected output 626 from data detector 624 to yield an interleaved output 632 which is stored in a memory 634. The interleaved output 636 from the memory 634 is provided to a non-binary low density parity check decoder with a format transforming variable node processor 640 which performs parity checks on the interleaved output 636, ensuring that parity constraints established by a low density parity check encoder (not shown) before storage or transmission are satisfied in order to detect and correct any errors that may have occurred in the data during storage or transmission.

Multiple detection and decoding iterations may be performed in the read channel 600, referred to herein as global iterations. (In contrast, local iterations are decoding iterations performed within non-binary low density parity check decoder with a format transforming variable node processor 640.) To perform a global iteration, likelihood values 642 from the non-binary low density parity check decoder with a format transforming variable node processor 640 are stored in memory 634, deinterleaved in a deinterleaver 646 to reverse the process applied by interleaver 630, and provided again to the data detector 624 to allow the data detector 624 to repeat the data detection process, aided by the log likelihood ratio values 642 from the non-binary low density parity check decoder with a format transforming variable node processor 640. In this manner, the read channel 600 can perform multiple global iterations, allowing the data detector 624 and low density parity check decoder 640 to converge on the correct data values.

The low density parity check decoder 640 also produces hard decisions 652 about the values of the data bits or symbols contained in the interleaved output 632 of the interleaver 630. The hard decisions 652 from the low density parity check decoder 640 are deinterleaved in a hard decision deinterleaver 654, reversing the process applied in interleaver 630, and stored in a hard decision memory 660 before being provided to a user or further processed. For example, the output 662 of the read channel 600 can be further processed to reverse formatting changes applied before storing data in a magnetic storage medium or transmitting the data across a transmission channel.

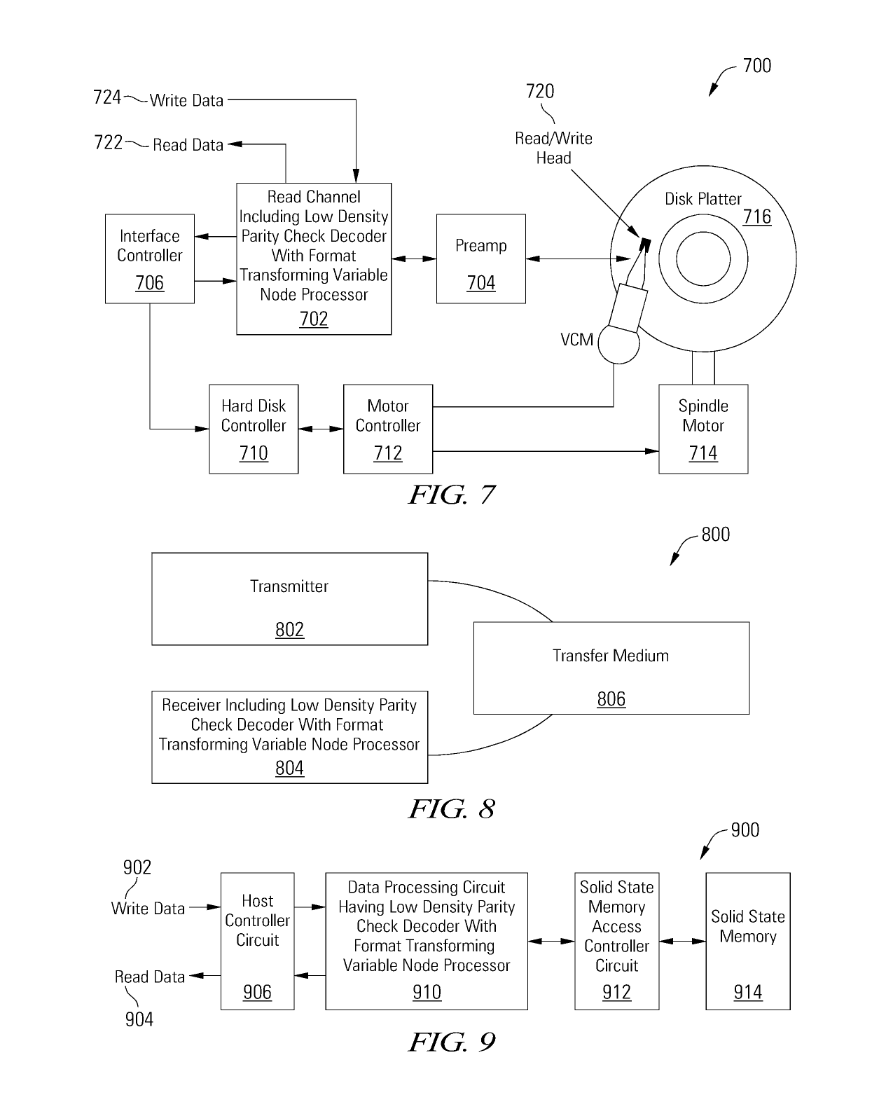

Turning to FIG. 7, a storage system 700 is illustrated as an example application of a non-binary low density parity check decoder with a format transforming variable node processor in accordance with some embodiments of the present invention. The storage system 700 includes a read channel circuit 702 with a non-binary low density parity check decoder with a format transforming variable node processor in accordance with one or more embodiments of the present invention. Storage system 700 may be, for example, a hard disk drive. Storage system 700 also includes a preamplifier 704, an interface controller 706, a hard disk controller 710, a motor controller 712, a spindle motor 714, a disk platter 716, and a read/write head assembly 720. Interface controller 706 controls addressing and timing of data to/from disk platter 716. The data on disk platter 716 consists of groups of magnetic signals that may be detected by read/write head assembly 720 when the assembly is properly positioned over disk platter 716. In one embodiment, disk platter 716 includes magnetic signals recorded in accordance with either a longitudinal or a perpendicular recording scheme.

In a typical read operation, read/write head assembly 720 is accurately positioned by motor controller 712 over a desired data track on disk platter 716. Motor controller 712 both positions read/write head assembly 720 in relation to disk platter 716 and drives spindle motor 714 by moving read/write head assembly 720 to the proper data track on disk platter 716 under the direction of hard disk controller 710. Spindle motor 714 spins disk platter 716 at a determined spin rate (RPMs). Once read/write head assembly 720 is positioned adjacent the proper data track, magnetic signals representing data on disk platter 716 are sensed by read/write head assembly 720 as disk platter 716 is rotated by spindle motor 714. The sensed magnetic signals are provided as a continuous, minute analog signal representative of the magnetic data on disk platter 716. This minute analog signal is transferred from read/write head assembly 720 to read channel circuit 702 via preamplifier 704. Preamplifier 704 is operable to amplify the minute analog signals accessed from disk platter 716. In turn, read channel circuit 702 digitizes the received analog signal and decodes the digital data in a non-binary low density parity check decoder with a format transforming variable node processor to recreate the information originally written to disk platter 716. This data is provided as read data 722 to a receiving circuit. A write operation is substantially the opposite of the preceding read operation with write data 724 being provided to read channel circuit 702. This data is then encoded and written to disk platter 716.

It should be noted that storage system 700 may be integrated into a larger storage system such as, for example, a RAID (redundant array of inexpensive disks or redundant array of independent disks) based storage system. Such a RAID storage system increases stability and reliability through redundancy, combining multiple disks as a logical unit. Data may be spread across a number of disks included in the RAID storage system according to a variety of algorithms and accessed by an operating system as if it were a single disk. For example, data may be mirrored to multiple disks in the RAID storage system, or may be sliced and distributed across multiple disks in a number of techniques. If a small number of disks in the RAID storage system fail or become unavailable, error correction techniques may be used to recreate the missing data based on the remaining portions of the data from the other disks in the RAID storage system. The disks in the RAID storage system may be, but are not limited to, individual storage systems such storage system 700, and may be located in close proximity to each other or distributed more widely for increased security. In a write operation, write data is provided to a controller, which stores the write data across the disks, for example by mirroring or by striping the write data. In a read operation, the controller retrieves the data from the disks. The controller then yields the resulting read data as if the RAID storage system were a single disk.

In addition, it should be noted that storage system 700 may be modified to include solid state memory that is used to store data in addition to the storage offered by disk platter 716. This solid state memory may be used in parallel to disk platter 716 to provide additional storage. In such a case, the solid state memory receives and provides information directly to read channel circuit 702. Alternatively, the solid state memory may be used as a cache where it offers faster access time than that offered by disk platter 716. In such a case, the solid state memory may be disposed between interface controller 706 and read channel circuit 702 where it operates as a pass through to disk platter 716 when requested data is not available in the solid state memory or when the solid state memory does not have sufficient storage to hold a newly written data set.

Based upon the disclosure provided herein, one of ordinary skill in the art will recognize a variety of storage systems including both disk platter 716 and a solid state memory.

Turning to FIG. 8, a wireless communication system 800 or data transmission device including a receiver 804 with a non-binary low density parity check decoder with a format transforming variable node processor is shown in accordance with some embodiments of the present invention. The transmitter 802 is operable to transmit encoded information via a transfer medium 806 as is known in the art. The encoded data is received from transfer medium 806 by receiver 804. Receiver 804 incorporates a non-binary low density parity check decoder with a format transforming variable node processor.

Turning to FIG. 9, another storage system 900 is shown that includes a data processing circuit 910 having a non-binary low density parity check decoder with a format transforming variable node processor in accordance with one or more embodiments of the present invention. A host controller circuit 906 receives data to be stored (i.e., write data 902). This data is provided to data processing circuit 910 where it is encoded using a low density parity check encoder. The encoded data is provided to a solid state memory access controller circuit 912.

Solid state memory access controller circuit 912 can be any circuit known in the art that is capable of controlling access to and from a solid state memory. Solid state memory access controller circuit 912 formats the received encoded data for transfer to a solid state memory 914. Solid state memory 914 can be any solid state memory known in the art. In some embodiments of the present invention, solid state memory 914 is a flash memory. Later, when the previously written data is to be accessed from solid state memory 914, solid state memory access controller circuit 912 requests the data from solid state memory 914 and provides the requested data to data processing circuit 910. In turn, data processing circuit 910 decodes the received data using a non-binary low density parity check decoder with a format transforming variable node processor. The decoded data is provided to host controller circuit 906 where it is passed on as read data 904.

It should be noted that the various blocks discussed in the above application may be implemented in integrated circuits along with other functionality. Such integrated circuits may include all of the functions of a given block, system or circuit, or a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some cases, parts of a given system, block or circuit may be implemented in software or firmware, while other parts are implemented in hardware.

In conclusion, embodiments of the present invention provide novel systems, devices, methods and arrangements for non-binary low density parity check decoding with a format transforming variable node processor. While detailed descriptions of one or more embodiments of the invention have been given above, various alternatives, modifications, and equivalents will be apparent to those skilled in the art without varying from the spirit of the invention. Therefore, the above description should not be taken as limiting the scope of embodiments of the invention which are encompassed by the appended claims.

What is claimed is:

1. A non-binary low density parity check decoder comprising:
a check node processor configured to generate check node to variable node messages based on variable node to check node messages; and
a variable node processor configured to generate the variable node to check node messages and to calculate perceived values of variable nodes based on the check node to variable node messages, wherein the variable node to check node messages and the check node to variable node messages are in a normalized format, the variable node processor comprising an adder configured to add likelihood values in a non-normalized format, wherein only one of two inputs to the adder are converted from the normalized format to the non-normalized format in a zero-padding circuit.

2. The decoder of claim 1, wherein the decoder comprises a layered decoder.

3. The decoder of claim 1, wherein the two inputs to the adder each comprise sets of log likelihood ratios in a Galois Field for a data symbol.

4. The decoder of claim 1, wherein a hard decision in an input to the zero-padding circuit is combined in an XOR operation with a second hard decision at an input to the adder.

5. The decoder of claim 1, wherein a second of the two inputs to the adder comprises a non-normalized set of log likelihood ratios generated in part by replacing a hard decision with a zero value.

6. The decoder of claim 1, further comprising a normalizing and rearranging circuit configured to normalize and rearrange log likelihood ratio values in an output of the adder in a combined operation.

7. The decoder of claim 6, wherein the normalizing and rearranging circuit is configured to rearrange the log likelihood ratio values according to a permutation factor from an H matrix.

8. The decoder of claim 6, wherein the normalizing and rearranging circuit is configured to combine a hard decision with a second hard decision at an input to the adder.

9. The decoder of claim 6, wherein the normalizing and rearranging circuit comprises a minimum finding circuit, a plurality of selection circuits connected to the minimum finding circuit, a plurality of multiplexers connected to the plurality of selection circuits, and a plurality of subtraction circuits connected to the plurality of multiplexers.

10. The decoder of claim 1, wherein the variable node processor comprises a subtraction circuit configured to subtract a first set of log likelihood ratios from a second set of log likelihood ratios, wherein the first set of log likelihood ratios is converted from a normalized format in a second zero-padding circuit.

11. The decoder of claim 10, wherein the second set of log likelihood ratios is converted from a normalized format in part by replacing a hard decision with a zero value.

12. A method of decoding data in a low density parity check decoder, comprising:
generating check node to variable node messages based on variable node to check node messages; and
generating variable node to check node messages based on the check node to variable node messages, said generating variable node to check node messages comprising adding a first set of log likelihood ratios to a second set of log likelihood ratios to yield a third set of log likelihood ratios, wherein the second set of log likelihood ratios is converted from a normalized format using a zero-padding circuit and wherein the first set of log likelihood ratios is not converted from the normalized format using any zero-padding circuit.

13. The method of claim 12, further comprising converting the first set of log likelihood ratios from the normalized format by replacing a hard decision with a zero value.

14. The method of claim 13, further comprising combining a second hard decision in an input to the zero-padding circuit with the hard decision using an XOR operation.

15. The method of claim 12, further comprising normalizing and rearranging the third set of log likelihood ratios in a combined normalizing and rearranging circuit.

16. The method of claim 15, further comprising combining a hard decision in an output of the combined normalizing and rearranging circuit with a second hard decision corresponding to the first set of log likelihood ratios using an XOR operation.

17. The method of claim 12, further comprising subtracting a third set of log likelihood ratios from a fourth set of log likelihood ratios to yield a fifth set of log likelihood ratios, wherein the third set of log likelihood ratios is converted from the normalized format using a second zero-padding circuit and wherein the fourth set of log likelihood ratios is not converted from the normalized format using any zero-padding circuit.

18. The method of claim 17, further comprising combining a hard decision in an input to the second zero-padding circuit with a second hard decision in an XOR operation.

19. A low density parity check decoder comprising:
check node processing means for generating check node to variable node messages based on variable node to check node messages; and
variable node processing means for updating variable node values based on the check node to variable node messages and for generating the variable node to check node messages, wherein a pair of normalized likelihood values are added in the variable node processing means after converting only one of the pair of normalized likelihood values to a non-normalized format in a zero-padding circuit.

20. The low density parity check decoder of claim 19, wherein the variable node processing means comprises combined normalizing and rearranging means.
